(19) United States
(12) Patent Application Publication
(10) Pub. No.: US 2024/0284681 A1
(43) Pub. Date: Aug. 22, 2024

(54) SEMICONDUCTOR DEVICE

(71) Applicant: ROHM Co., LTD., Kyoto (JP)

(72) Inventors: Noriyuki Shimoji, Kyoto (JP); Shinichi Tahara, Kyoto (JP); Ken Nakahara, Kyoto (JP)

(21) Appl. No.: 18/434,981

(22) Filed: Feb. 7, 2024

(30) Foreign Application Priority Data
Feb. 22, 2023 (JP) 2023-026378

(51) Int. Cl. H10B 51/30; H01L 29/20; H01L 29/51; H01L 29/778

(52) U.S. Cl. CPC H10B 51/30; H01L 29/2003; H01L 29/516; H01L 29/7786

(57) ABSTRACT

Provided is a semiconductor device including a field effect transistor that has a first terminal connected to a load, a second terminal conducting to the first terminal via a channel, and a control terminal that controls conduction and interruption of the channel by an electric field, and a nonvolatile memory that is a nonvolatile memory connected to the control terminal and has a second control terminal supplied with a voltage that changes a direction of the electric field from the control terminal.

### CROSS REFERENCE TO RELATED APPLICATIONS

This application claims priority benefit of Japanese Patent Application No. JP 2023-026378 filed in the Japan Patent Office on Feb. 22, 2023. Each of the above-referenced applications is hereby incorporated herein by reference in its entirety.

### BACKGROUND

The present disclosure relates to a semiconductor device.

Japanese Patent Laid-open No. 2021-47743 discloses an electronic apparatus including an interface that has a first terminal supplied with a first signal, a second terminal, and a power supply terminal, a first voltage dividing unit that has a plurality of resistances and a fuse, converts the first signal to a different voltage level according to a conduction state of the fuse, and outputs the first signal, a first transistor that is turned on or off on the basis of the first signal whose voltage level is converted, a second transistor that is controlled to be off when the first transistor is on and is controlled to be on or off on the basis of a second signal when the first transistor is off, a conduction control element whose one end and another end are connected to each other or disconnected from each other according to a conduction state of the second transistor and that supplies a power supply voltage from the one end to the other end, and a power supply circuit.

### BRIEF DESCRIPTION OF THE DRAWINGS

FIG. 1 is a schematic sectional view of a semiconductor device according to a first embodiment of the present disclosure;

FIG. 2 is a diagram illustrating a modification of a memory structure in FIG. 1;

FIG. 3 is a diagram illustrating a circuit configuration of the semiconductor device in FIG. 1;

FIG. 4 is a diagram illustrating a first example of a connection circuit connecting the semiconductor device of FIG. 1 to a load;

FIG. 5 is a schematic sectional view of a semiconductor device according to a second embodiment of the present disclosure;

FIG. 6 is a diagram illustrating a circuit configuration of the semiconductor device in FIG. 5;

FIG. 7 is a diagram illustrating a first example of a connection circuit connecting the semiconductor device of FIG. 5 to a load;

FIG. 8 is a diagram illustrating a second example of the connection circuit connecting the semiconductor device of FIG. 5 to the load;

FIG. 9 is a diagram illustrating a third example of the connection circuit connecting the semiconductor device of FIG. 5 to the load;

FIG. 10 is a diagram illustrating a fourth example of the connection circuit connecting the semiconductor device of FIG. 5 to the load;

FIG. 11 is a schematic sectional view of a semiconductor device according to a third embodiment of the present disclosure;

FIG. 12 is a diagram illustrating a circuit configuration of the semiconductor device in FIG. 11;

FIG. 13 is a schematic sectional view of a semiconductor device according to a fourth embodiment of the present disclosure;

FIG. 14 is a diagram illustrating a circuit configuration of the semiconductor device in FIG. 13;

FIG. 15 is a schematic sectional view of a semiconductor device according to a fifth embodiment of the present disclosure;

FIG. 16 is a schematic sectional view of a semiconductor device according to a sixth embodiment of the present disclosure;

FIG. 17 is a schematic sectional view of a semiconductor device according to a seventh embodiment of the present disclosure; and

FIG. 18 is a schematic sectional view of a semiconductor device according to an eighth embodiment of the present disclosure.

### DETAILED DESCRIPTION

Next, embodiments of the present disclosure will be described in detail with reference to the accompanying drawings.

### First Embodiment

### (1) Structure of Semiconductor Device 1A

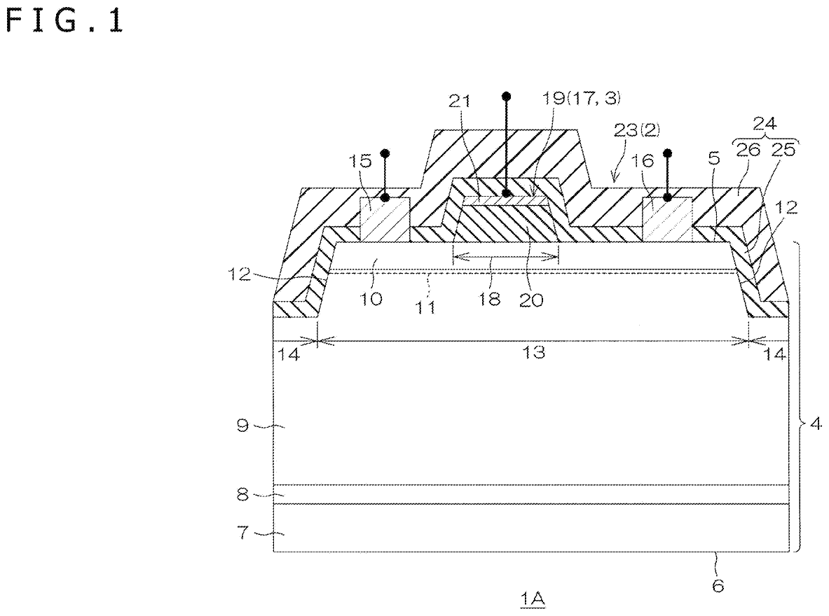

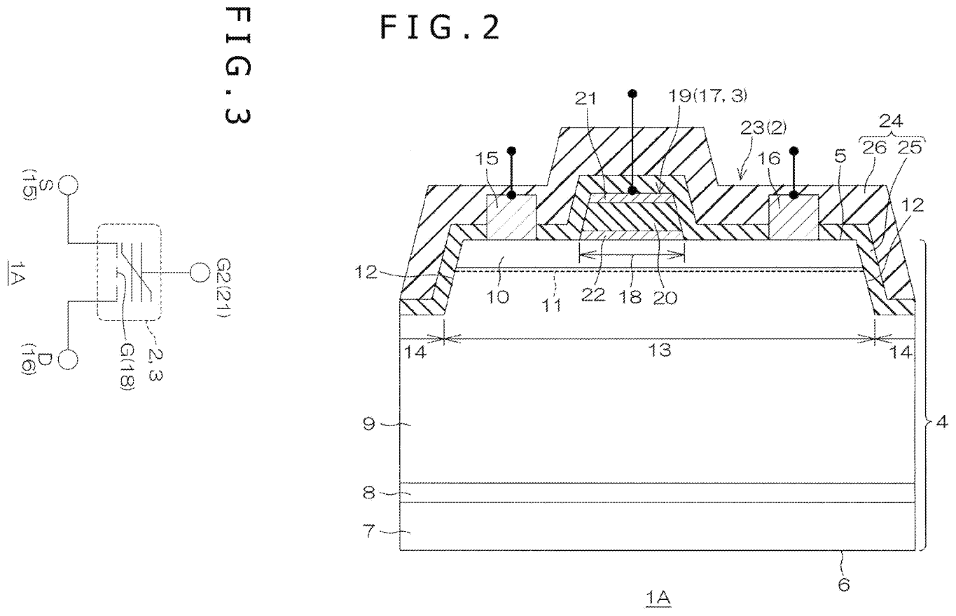

FIG. 1 is a schematic sectional view of a semiconductor device 1A according to a first embodiment of the present disclosure. FIG. 2 is a diagram illustrating a modification of a memory structure 19 in FIG. 1.

The semiconductor device 1A is a current interrupting element constituted by a combination of a field effect transistor 2 and a nonvolatile memory 3. The semiconductor device 1A interrupts an electronic circuit in which the semiconductor device 1A itself is incorporated when a malfunction or a failure occurs in the circuit. It is thereby possible to protect the circuit including the semiconductor device 1A and a circuit adjacent to the circuit including the semiconductor device 1A without affecting these circuits. The circuit in which the semiconductor device 1A is incorporated may be, for example, various kinds of electronic circuits such as an inverter circuit, a converter circuit, and a control circuit.

The semiconductor device 1A in the present embodiment is a nitride semiconductor device. The semiconductor device 1A includes a semiconductor chip 4 that has a first principal surface 5 and a second principal surface 6 on an opposite side from the first principal surface 5.

The semiconductor chip 4 includes a substrate 7, a buffer layer 8 formed on the substrate 7, a first nitride semiconductor layer 9 epitaxially grown on the buffer layer 8, and a second nitride semiconductor layer 10 epitaxially grown on the first nitride semiconductor layer 9.

The substrate 7 may be, for example, a low-resistance silicon substrate. The low-resistance silicon substrate may be, for example, a p-type substrate having an electric resistivity equal to or more than 0.001 Ωmm and equal to or less than 0.5 Ωmm (more specifically, approximately equal to or more than 0.01 Ωmm and equal to or less than 0.1 Ωmm). The substrate 7 may be not only a low-resistance silicon substrate but also a low-resistance SiC substrate, a low-resistance GaN substrate, or other substrates. The thickness of the substrate 7 is, for example, approximately 650 μm during a semiconductor process, and the substrate 7 may be ground to approximately 300 μm or less in a stage before chipping.

The buffer layer 8 may be formed by, for example, a multilayer buffer layer in which a plurality of nitride semiconductor films are laminated. In the present embodiment, the buffer layer 8 is formed by a first buffer layer (not illustrated) constituted by an AlN film in contact with the surface of the substrate 7 and a second buffer layer (not illustrated) constituted by a graded AlGaN layer laminated to the surface (surface on an opposite side from the substrate 7) of the first buffer layer.

The film thickness of the first buffer layer may be approximately equal to or more than 100 nm and equal to or less than 500 nm. The film thickness of the second buffer layer may be approximately equal to or more than 400 nm and equal to or less than 1 μm as a total of those of three AlGaN layers having Al compositions of 75%, 50%, and 25% in order from the first buffer layer side and having a same film thickness. The number of graded AlGaN layers constituting the second buffer layer and respective film thickness ratios thereof may be different. The buffer layer 8 may be formed by, for example, a single film of AlGaN, an AlGaN/GaN superlattice film, an AlN/AlGaN superlattice film, or an AlN/GaN superlattice film.

The first nitride semiconductor layer 9 constitutes an electron transit layer. In the present embodiment, the first nitride semiconductor layer 9 may be constituted by a GaN layer, and a thickness thereof may be approximately equal to or more than 0.5 μm and equal to or less than 2 μm. For a purpose of suppressing a leakage current flowing through the first nitride semiconductor layer 9, an impurity for imparting a semi-insulating property may be introduced into a part other than a surface portion of the first nitride semiconductor layer 9. In that case, the concentration of the impurity is preferably equal to or higher than 4×10¹⁶ cm⁻³. In addition, the impurity may be C, for example.

The second nitride semiconductor layer 10 constitutes an electron supply layer. The second nitride semiconductor layer 10 is constituted by a nitride semiconductor having a larger band gap than the first nitride semiconductor layer 9. Specifically, the second nitride semiconductor layer 10 is constituted by a nitride semiconductor having a higher Al composition than the first nitride semiconductor layer 9. In a nitride semiconductor, the higher the Al composition, the larger the band gap. In the present embodiment, the second nitride semiconductor layer 10 is constituted by an AlₓGa₁₋ₓN layer (0.1<x≤0.4). The Al composition of the second nitride semiconductor layer 10 is preferably equal to or lower than 40%. That is, x is preferably equal to or less than 0.4. Specifically, x is preferably equal to or more than 0.1 and equal to or less than 0.4, and is more preferably equal to or more than 0.15 and equal to or less than 0.3. The thickness of the second nitride semiconductor layer 10 is preferably equal to or more than 8 nm and equal to or less than 20 nm.

The first nitride semiconductor layer 9 (electron transit layer) and the second nitride semiconductor layer 10 (electron supply layer) are thus constituted by nitride semiconductors having different band gaps (Al compositions), and lattice constants thereof are different from each other in bulk regions. Then, due to the spontaneous polarization of the first nitride semiconductor layer 9 and the second nitride semiconductor layer 10 and piezopolarization caused by a lattice mismatched heterojunction between the first nitride semiconductor layer 9 and the second nitride semiconductor layer 10, the energy level of a conduction band of the first nitride semiconductor layer 9 at an interface between the first nitride semiconductor layer 9 and the second nitride semiconductor layer 10 is lower than a Fermi level. Consequently, within the first nitride semiconductor layer 9, a two-dimensional electron gas 11 is spread at a position close to the interface between the first nitride semiconductor layer 9 and the second nitride semiconductor layer 10 (for example, at a distance of approximately a few nm from the interface).

The semiconductor chip 4 includes a mesa laminated portion 13 having a wall surface 12 that crosses the second nitride semiconductor layer 10 and the first nitride semiconductor layer 9 in a thickness direction. The first nitride semiconductor layer 9 (electron transit layer) includes an extending portion 14 that extends from the mesa laminated portion 13 in a direction intersecting the lamination direction of the mesa laminated portion 13.

The semiconductor device 1A includes a source electrode 15 as an example of a second electrode, a drain electrode 16 as an example of a first electrode, and a gate portion 17.

The source electrode 15 and the drain electrode 16 are formed on the surface of the mesa laminated portion 13 (first principal surface 5 of the semiconductor chip 4). The source electrode 15 and the drain electrode 16 are arranged at a distance from each other.

The source electrode 15 and the drain electrode 16 may have, for example, a laminated structure of a first metal layer (ohmic metal layer) in contact with the second nitride semiconductor layer 10, a second metal layer (main electrode metal layer) laminated to the first metal layer, a third metal layer (close contact layer) laminated to the second metal layer, and a fourth metal layer (barrier metal layer) laminated to the third metal layer.

The first metal layer is, for example, a Ti layer having a thickness approximately equal to or more than 10 nm and equal to or less than 20 nm. The second metal layer is, for example, an Al layer having a thickness approximately equal to or more than 100 nm and equal to or less than 300 nm. The third metal layer is, for example, a Ti layer having a thickness approximately equal to or more than 10 nm and equal to or less than 20 nm. The fourth metal layer is, for example, a TiN layer having a thickness approximately equal to or more than 10 nm and equal to or less than 50 nm.

In the semiconductor device 1A, the second nitride semiconductor layer 10 (electron supply layer) having a different band gap (Al composition) from the first nitride semiconductor layer 9 (electron transit layer) is formed on the first nitride semiconductor layer 9, so that a heterojunction is formed. Consequently, the two-dimensional electron gas 11 is formed within the first nitride semiconductor layer 9 and in the vicinity of the interface between the first nitride semiconductor layer 9 and the second nitride semiconductor layer 10, and a high electron mobility transistor (HEMT) (transistor) using the two-dimensional electron gas 11 as a channel is formed.

In the present embodiment, a transistor structure 23 of a normally-on type is formed in which the two-dimensional electron gas 11 traverses the gate portion 17 along the first principal surface 5 and spreads from the source electrode 15 to the drain electrode 16 in a normal state. In a case of the transistor structure 23 of the normally-on type, it is not necessary to apply a voltage at all times in order to make a channel conduct. Hence, a power supply circuit for the transistor structure 23 can be omitted, so that the semiconductor device 1A having a simple structure can be provided.

The semiconductor device 1A according to the present embodiment is a GaN-HEMT in which the first nitride semiconductor layer 9 is a GaN layer. The transistor structure 23 may therefore be referred to as a power transistor structure. The power transistor structure may be used in, for example, not only a GaN device but also in a transistor structure in which a wide band gap semiconductor such as GaAs or Sic is used as a main material.

The gate portion 17 controls the conduction and interruption of the two-dimensional electron gas 11 (channel) between the source electrode 15 and the drain electrode 16. In the present embodiment, a region on which the gate portion 17 is laminated at the surface of the second nitride semiconductor (first principal surface 5 of the semiconductor chip 4) is a channel control region 18. The two-dimensional electron gas 11 (channel) conducts or is interrupted directly below the channel control region 18.

Referring to FIG. 1, the gate portion 17 has the memory structure 19 including at least a ferroelectric film 20 laminated directly on the channel control region 18 and an upper electrode 21 laminated on the ferroelectric film 20. The semiconductor device 1A has the transistor structure 23 integral with the memory structure 19 (HEMT structure). Referring to FIG. 2, the gate portion 17 may further include a lower electrode 22 sandwiched between the ferroelectric film 20 and the channel control region 18.

The ferroelectric film 20 in the present embodiment is one of a single crystal PZT (lead zirconate titanate) thin film, a polycrystalline PZT thin film, and a BST ((Ba, Sr) TiO₃) thin film. The ferroelectric film 20 can be, for example, formed by a method such as an epitaxial growth method, a sputtering method, a metal-organic chemical vapor deposition (MOCVD) method, or a sol-gel method. The thickness of the ferroelectric film 20 may be, for example, equal to or more than 0.15 μm and equal to or less than 1.0 μm.

The upper electrode 21 may have, for example, a laminated structure of a first metal layer in contact with the ferroelectric film 20 and a second metal layer laminated to the first metal layer. In the present embodiment, the first metal layer of the upper electrode 21 is, for example, an IrO₂ (iridium oxide) layer having a thickness approximately equal to or more than 40 nm and equal to or less than 100 nm. The second metal layer of the upper electrode 21 is, for example, an Ir (iridium) layer having a thickness approximately equal to or more than 40 nm and equal to or less than 100 nm.

The lower electrode 22 in the present embodiment is a Pt (platinum) layer having a thickness approximately equal to or more than 100 nm and equal to or less than 200 nm.

The semiconductor device 1A further includes a passivation film 24 that covers the second nitride semiconductor layer 10. The passivation film 24 in the present embodiment covers the entire surfaces of the mesa laminated portion 13 and the extending portion 14. The passivation film 24 may have, for example, a laminated structure of a first insulating film 25 in contact with the second nitride semiconductor layer 10 and a second insulating film 26 laminated to the first insulating film 25. In the present embodiment, the first insulating film 25 of the passivation film 24 is, for example, a SiN (silicon nitride) film having a thickness approximately equal to or more than 100 nm and equal to or less than 200 nm. The second insulating film 26 of the passivation film 24 is, for example, a SiO₂ (silicon oxide) film having a thickness approximately equal to or more than 500 nm and equal to or less than 1000 nm. The passivation film 24 may be formed by a single film as one of a SiN film, a SiO₂ film, a SiON film, an Al₂O₃ film, an AlN film, an AlON film, and a ZrO₂ film or a composite film constituted by a given combination of two or more of these films.

In using the semiconductor device 1A, a predetermined voltage (for example, equal to or higher than 1 V and equal to or lower than 40 V) that is positive on the drain electrode 16 side, for example, is applied between the source electrode 15 and the drain electrode 16. Because the semiconductor device 1A is a HEMT of the normally-on type, conduction occurs between the source and the drain via the two-dimensional electron gas 11 in this state. In order to effect interruption between the source and the drain, with the source electrode 15 set at a reference potential (0 V), a voltage lower than a threshold voltage Vth (<0) is applied to the upper electrode 21 of the gate portion 17. Consequently, a positive charge (positive holes) and a negative charge (electrons) in the ferroelectric film 20 are spatially separated from each other, thus causing a spontaneous polarization. The positive charge is gathered on the upper electrode 21 side. The negative charge is gathered on the channel control region 18 side. The two-dimensional electron gas 11 disappears directly below the channel control region 18 due to an electric repulsion (repulsive force) between the negative charge on the channel control region 18 side and the electrons of the two-dimensional electron gas 11. The interruption between the source and the drain is thereby effected.

### (2) Example of Connection Circuit of Semiconductor Device 1A

FIG. 3 is a diagram illustrating a circuit configuration of the semiconductor device 1A in FIG. 1. The semiconductor device 1A has the transistor structure 23 integral with the memory structure 19 (HEMT structure), which is formed by a combination of the field effect transistor 2 having the transistor structure 23 and the nonvolatile memory 3 having the memory structure 19, and the semiconductor device 1A has the circuit configuration of FIG. 3.

Referring to FIGS. 1 to 3, the semiconductor device 1A includes a drain D as an example of a first terminal corresponding to the drain electrode 16, a source S as an example of a second terminal corresponding to the source electrode 15, a gate G as an example of a control terminal corresponding to the channel control region 18, and a second gate G2 as an example of a second control terminal corresponding to the upper electrode 21. The semiconductor device 1A does not have an independent gate electrode in the channel control region 18 as a gate of the transistor structure 23, but the memory structure 19 is directly formed as the gate portion 17 on the channel control region 18.

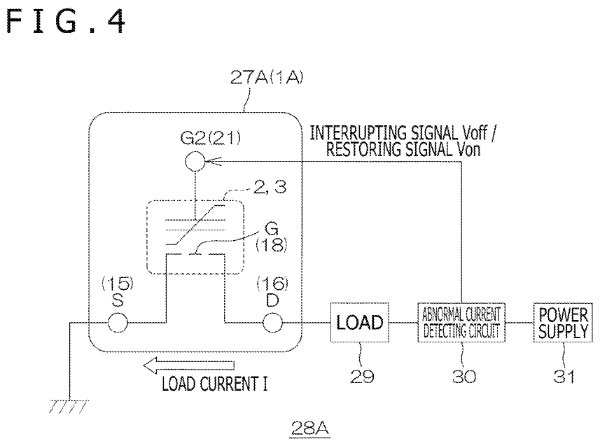

FIG. 4 is a diagram illustrating a first example of a connection circuit connecting the semiconductor device 1A of FIG. 1 to a load 29. The semiconductor device 1A having the circuit configuration of FIG. 3 can be incorporated in an electronic circuit 28A illustrated in FIG. 4, for example.

Referring to FIG. 4, the electronic circuit 28A may be, for example, various kinds of electronic circuits such as an inverter circuit, a converter circuit, and a control circuit. The electronic circuit 28A may include a current interrupting element 27A constituted by the semiconductor device 1A, the load 29, and an abnormal current detecting circuit 30. The source S of the current interrupting element 27A is grounded. The drain D of the current interrupting element 27A is connected to the load 29.

The load 29 is, for example, connected to a power supply 31 via the abnormal current detecting circuit 30. Cited as the load 29 is, for example, an inverter circuit, a boosting circuit, a rectifier circuit, or other circuits for the control of a motor mounted in a power control apparatus (an air conditioner, a refrigerator, or other home appliances), an EV (Electric Vehicle), an HEV (Hybrid Electric Vehicle), an electric railway, or other vehicles, photovoltaic power generation, or power supply control (battery).

The abnormal current detecting circuit 30 detects an abnormal mode that occurs in the load 29. The abnormal mode of the load 29 may include, for example, an overcurrent, a short circuit, heating, a reverse current, an overvoltage, and a low voltage. The abnormal current detecting circuit 30 is connected to the second gate G2 of the current interrupting element 27A. An interrupting signal Voff and a restoring signal Von for the current interrupting element 27A are input from the abnormal current detecting circuit 30.

Description will be made of the detection of an abnormal current from a start of operation of the load 29 in the electronic circuit 28A and a subsequent restoring operation. Referring to FIG. 4, for example, the current interrupting element 27A is initialized to a normally-on state by a polling signal (for example, a voltage of ±5 V) to the nonvolatile memory 3.

Next, a voltage (for example, a voltage lower than −3 V) that is lower than a gate threshold voltage Vth of the field effect transistor 2 is applied to the second gate G2. Consequently, the positive charge (positive holes) and the negative charge (electrons) in the ferroelectric film 20 are spatially separated from each other, thus causing a spontaneous polarization. The two-dimensional electron gas 11 thereby disappears directly below the channel control region 18 (gate G), so that the interruption between the source S and the drain D (source-to-drain) is effected. This process is to prevent an excessive voltage from being applied to the load 29 at a time of connecting the electronic circuit 28A to the power supply 31, and may be omitted as necessary.

Next, a voltage necessary for the operation of the load 29 is applied to the drain D. Then, the abnormal current detecting circuit 30 is connected between the power supply 31 and the load 29. Next, a voltage (for example, a voltage equal to or higher than 0 V) that is equal to or higher than a source voltage and equal to or higher than the gate threshold voltage Vth is applied to the second gate G2. Consequently, a polarization reversal of the positive charge (positive holes) and the negative charge (electrons) in the ferroelectric film 20 occurs. The negative charge is gathered on the upper electrode 21 side. The positive charge is gathered on the channel control region 18 side. The two-dimensional electron gas 11 occurs directly below the channel control region 18 due to an electric attraction (attractive force) between the positive charge on the channel control region 18 (gate G) side and the electrons of the two-dimensional electron gas 11. In an operating state of the load 29, a load current I starts to flow between the source S and the drain D (source-to-drain) via the two-dimensional electron gas 11, and thus conduction occurs between the source and the drain.

When an abnormality occurs in the load 29, and an overcurrent flows between the source and the drain, for example, the interrupting signal Voff (<Gate Threshold Voltage Vth) is input to the gate G by a reaction of the abnormal current detecting circuit 30. Consequently, a polarization reversal of the positive charge (positive holes) and the negative charge (electrons) in the ferroelectric film 20 occurs. The positive charge is gathered on the upper electrode 21 side. The negative charge is gathered on the channel control region 18 side. An interruption between the source and the drain is thereby effected, so that the operation of the load 29 is stopped.

Thereafter, the gate G is set in an open state. However, due to a characteristic of residual polarization of the nonvolatile memory 3 (ferroelectric film 20), the disappearance of the two-dimensional electron gas 11 between the source and the drain is continued, so that the interruption between the source and the drain is maintained.

When it is confirmed that the load 29 is in a normal state, the restoring signal Von (≥Gate Threshold Voltage Vth) is input from the abnormal current detecting circuit 30 to the second gate G2. Consequently, a polarization reversal of the positive charge (positive holes) and the negative charge (electrons) in the ferroelectric film 20 occurs again. The negative charge is gathered on the upper electrode 21 side. The positive charge is gathered on the channel control region 18 side. Conduction between the source and the drain thereby occurs, so that the operation of the load 29 is resumed.

As described above, according to the semiconductor device 1A, when an abnormality occurs in the load 29, the interrupting signal Voff is input to the gate G, and thus the voltage supplied to the second gate G2 is controlled appropriately. Consequently, the direction of an electric field from the channel control region 18 is changed via the second gate G2, so that the channel of the field effect transistor 2 is interrupted. Thus, the load current I can be interrupted. As a result, the electronic circuit 28A and a circuit adjacent to the electronic circuit 28A can be protected. In addition, the electronic circuit 28A is interrupted by switching operation of the field effect transistor 2, and can therefore be interrupted at a high speed as compared with other current interrupting elements (for example, a fuse and a poly-switch).

In addition, an element that controls the electric field direction of the field effect transistor 2 is the nonvolatile memory 3. Therefore, unless the restoring signal Von for restoring the nonvolatile memory 3 to an initial state is intentionally input to the nonvolatile memory 3 after the interruption of the channel, the disappearance of the two-dimensional electron gas 11 between the source and the drain is continued due to the characteristic of residual polarization of the nonvolatile memory 3 (ferroelectric film 20). Thus, the interruption is maintained without the conduction of the channel between the source and the drain. Hence, it is possible to prevent an accidental conduction of the channel of the field effect transistor 2 and a flow of a current to the load 29 before it is confirmed that the load 29 is in a normal state.

In addition, the field effect transistor 2 and the nonvolatile memory 3 are formed on the common semiconductor chip 4. It is therefore possible to provide, on one chip, the semiconductor device 1A that can interrupt the electronic circuit 28A at a high speed, and can prevent an accidental restoration before it is confirmed that the load 29 is in a normal state.

In addition, the memory structure 19 is laminated, as the gate portion 17 of the field effect transistor 2, directly on the channel control region 18. It is thereby possible to reduce wiring losses at times of control of the conduction and interruption of the channel by the memory structure 19.

Further, when the lower electrode 22 is interposed between the ferroelectric film 20 and the semiconductor chip 4 as illustrated in FIG. 2, the lower electrode 22 can hinder the diffusion of a ferroelectric material into the semiconductor chip 4. It is thereby possible to suppress a change in the characteristics of the field effect transistor 2.

### Second Embodiment

In the following, structures corresponding to the structures described with respect to the semiconductor device 1A are identified by the same reference signs, and description thereof will be omitted.

### (1) Structure of Semiconductor Device 1B

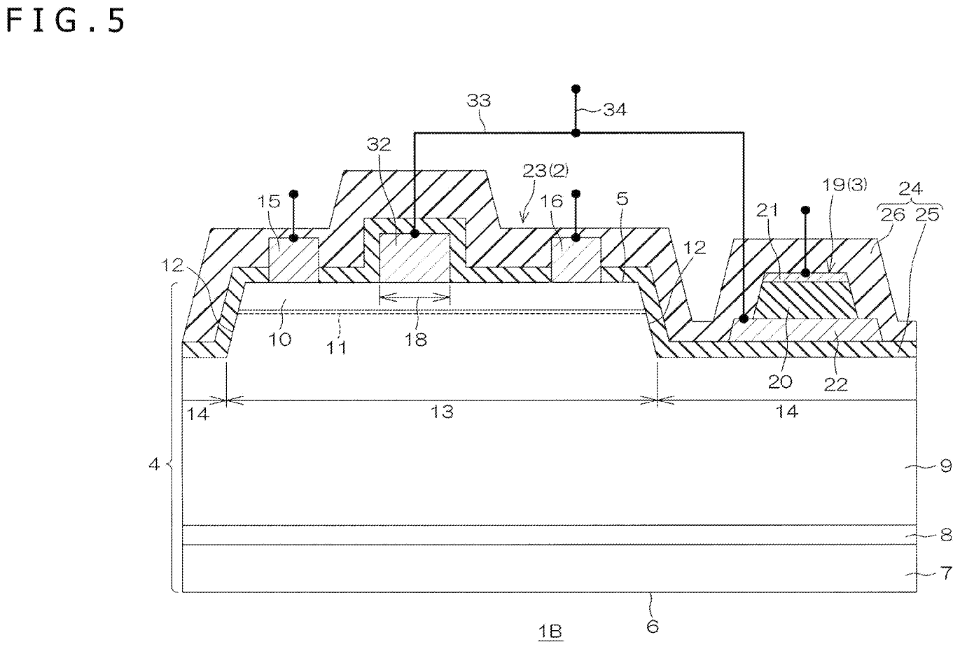

FIG. 5 is a schematic sectional view of a semiconductor device 1B according to a second embodiment of the present disclosure.

The semiconductor device 1B has a commonality with the semiconductor device 1A in that the semiconductor device 1B is provided with the transistor structure 23 and the memory structure 19 on the common semiconductor chip 4. On the other hand, in the semiconductor device 1B, the memory structure 19 is not laminated directly on the channel control region 18 as in the semiconductor device 1A, but is disposed in a region separated from the channel control region 18 along the principal surface of the semiconductor chip 4. In the present embodiment, the memory structure 19 is disposed on the passivation film 24 in the extending portion 14 of the semiconductor chip 4. More specifically, the memory structure 19 is formed on the first insulating film 25 of the passivation film 24, and the second insulating film 26 covers the memory structure 19. Hence, in the present embodiment, the two-dimensional electron gas 11 is not present directly below the memory structure 19.

In the semiconductor device 1B, a gate electrode 32 as an example of a control electrode is laminated directly on the channel control region 18. The gate electrode 32 controls the conduction and interruption of the two-dimensional electron gas 11 (channel) between the source electrode 15 and the drain electrode 16. The gate electrode 32 is TiN, for example. The thickness of the gate electrode 32 is, for example, equal to or more than 60 nm and equal to or less than 200 nm. The gate electrode 32 may be formed by a single film as one of a Ti film, a TiN film, and a TiW film or a composite film constituted by a given combination of two or more of these films.

The lower electrode 22 and the gate electrode 32 of the memory structure 19 are electrically connected to each other by intermediate wiring 33. Branch wiring 34 branched from the intermediate wiring 33 may be further connected to a middle portion of the intermediate wiring 33. Incidentally, though not illustrated in the figure, the lower electrode 22 and the gate electrode 32 may be common wiring.

In using the semiconductor device 1B, a predetermined voltage (for example, equal to or higher than 1 V and equal to or lower than 40 V) that is positive on the drain electrode 16 side, for example, is applied between the source electrode 15 and the drain electrode 16. Because the semiconductor device 1B is a HEMT of the normally-on type, conduction occurs between the source and the drain via the two-dimensional electron gas 11 in this state. In order to effect interruption between the source and the drain, with the source electrode 15 set at a reference potential (0 V), a voltage lower than a threshold voltage Vth (<0) is applied to the upper electrode 21 of the memory structure 19. Consequently, a positive charge (positive holes) and a negative charge (electrons) in the ferroelectric film 20 are spatially separated from each other, thus causing a spontaneous polarization. The positive charge is gathered on the upper electrode 21 side. The negative charge is gathered on the lower electrode 22 side. The potential of the gate electrode 32 becomes the same potential (negative potential) as that of the lower electrode 22 via the intermediate wiring 33. The two-dimensional electron gas 11 therefore disappears directly below the gate electrode 32 due to an electric repulsion (repulsive force) between the gate electrode 32 and the electrons of the two-dimensional electron gas 11. The interruption between the source and the drain is thereby effected.

### (2) Example of Connection Circuit of Semiconductor Device 1B

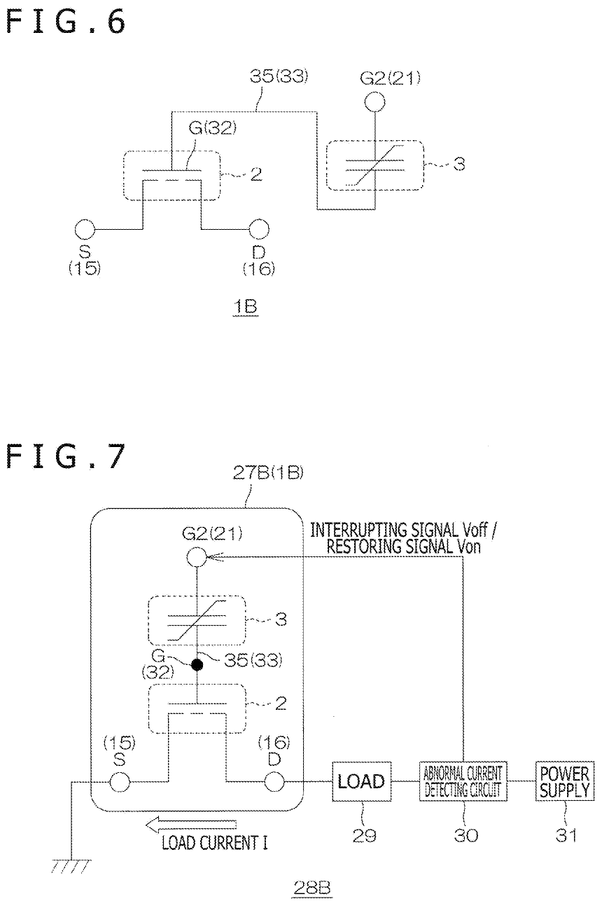

FIG. 6 is a diagram illustrating a circuit configuration of the semiconductor device 1B in FIG. 5. The semiconductor device 1B has the transistor structure 23 including the memory structure 19 on one chip (HEMT structure), which is formed by a combination of the field effect transistor 2 having the transistor structure 23 and the nonvolatile memory 3 having the memory structure 19, and the semiconductor device 1B has the circuit configuration of FIG. 6.

Referring to FIG. 5 and FIG. 6, the semiconductor device 1B includes a drain D as an example of a first terminal corresponding to the drain electrode 16, a source S as an example of a second terminal corresponding to the source electrode 15, a gate G as an example of a control terminal corresponding to the gate electrode 32, and a second gate G2 as an example of a second control terminal corresponding to the upper electrode 21. A connection between the gate G of the field effect transistor 2 and the nonvolatile memory 3 is established by an intermediate line 35 corresponding to the intermediate wiring 33.

Referring to FIGS. 7 to 10, four examples of a connection circuit connecting the semiconductor device 1B to the load 29 will be introduced.

FIG. 7 is a diagram illustrating a first example of the connection circuit connecting the semiconductor device 1B of FIG. 5 to the load 29. The semiconductor device 1B having the circuit configuration of FIG. 6 can be incorporated in an electronic circuit 28B illustrated in FIG. 7, for example.

Referring to FIG. 7, the electronic circuit 28B may be, for example, various kinds of electronic circuits such as an inverter circuit, a converter circuit, and a control circuit. The electronic circuit 28B may include a current interrupting element 27B constituted by the semiconductor device 1B, a load 29, and an abnormal current detecting circuit 30. The source S of the current interrupting element 27B is grounded. The drain D of the current interrupting element 27B is connected to the load 29.

The load 29 is, for example, connected to a power supply 31 via the abnormal current detecting circuit 30. Cited as the load 29 is, for example, an inverter circuit, a boosting circuit, a rectifier circuit, or other circuits for the control of a motor mounted in a power control apparatus (an air conditioner, a refrigerator, or other home appliances), an EV (Electric Vehicle), an HEV (Hybrid Electric Vehicle), an electric railway, or other vehicles, photovoltaic power generation, or power supply control (battery).

The abnormal current detecting circuit 30 detects an abnormal mode that occurs in the load 29. The abnormal mode of the load 29 may include, for example, an overcurrent, a short circuit, heating, a reverse current, an overvoltage, and a low voltage. The abnormal current detecting circuit 30 is connected to the second gate G2 of the current interrupting element 27B. An interrupting signal and a restoring signal for the current interrupting element 27B are input from the abnormal current detecting circuit 30.

Description will be made of the detection of an abnormal current from a start of operation of the load 29 in the electronic circuit 28B and a subsequent restoring operation. Referring to FIG. 7, for example, the current interrupting element 27B is initialized to a normally-on state by a polling signal (for example, a voltage of ±5 V) to the nonvolatile memory 3.

Next, a voltage (for example, a voltage lower than −3 V) that is lower than the gate threshold voltage Vth of the field effect transistor 2 is applied to the second gate G2. Consequently, the positive charge (positive holes) and the negative charge (electrons) in the ferroelectric film 20 are spatially separated from each other, thus causing a spontaneous polarization. The two-dimensional electron gas 11 thereby disappears directly below the gate electrode 32 (gate G), so that the interruption between the source S and the drain D (source-to-drain) is effected. This process is to prevent an excessive voltage from being applied to the load 29 at a time of connecting the electronic circuit 28B to the power supply 31, and may be omitted as necessary.

Next, a voltage necessary for the operation of the load 29 is applied to the drain D. Then, the abnormal current detecting circuit 30 is connected between the power supply 31 and the load 29. Next, a voltage (for example, a voltage equal to or higher than −3 V) that is equal to or higher than the gate threshold voltage Vth is applied to the second gate G2. Consequently, a polarization reversal of the positive charge (positive holes) and the negative charge (electrons) in the ferroelectric film 20 occurs. The negative charge is gathered on the upper electrode 21 side. The positive charge is gathered on the lower electrode 22 side. The two-dimensional electron gas 11 occurs directly below the gate electrode 32 due to an electric attraction (attractive force) between the gate electrode 32 (gate G) consequently set to a positive potential and the electrons of the two-dimensional electron gas 11. In an operating state of the load 29, a load current I starts to flow between the source S and the drain D (source-to-drain) via the two-dimensional electron gas 11, and thus conduction occurs between the source and the drain.

When an abnormality occurs in the load 29, and an overcurrent flows between the source and the drain, for example, the interrupting signal Voff (<Gate Threshold Voltage Vth) is input to the gate G by a reaction of the abnormal current detecting circuit 30. Consequently, a polarization reversal of the positive charge (positive holes) and the negative charge (electrons) in the ferroelectric film 20 occurs. The positive charge is gathered on the upper electrode 21 side. The negative charge is gathered on the lower electrode 22 side. An interruption between the source and the drain is thereby effected, so that the operation of the load 29 is stopped.

Thereafter, the gate G is set in an open state. However, due to a characteristic of residual polarization of the nonvolatile memory 3 (ferroelectric film 20), the disappearance of the two-dimensional electron gas 11 between the source and the drain is continued, so that the interruption between the source and the drain is maintained.

When it is confirmed that the load 29 is in a normal state, the restoring signal Von (≥Gate Threshold Voltage Vth) is input from the abnormal current detecting circuit 30 to the second gate G2. Consequently, a polarization reversal of the positive charge (positive holes) and the negative charge (electrons) in the ferroelectric film 20 occurs again. The negative charge is gathered on the upper electrode 21 side. The positive charge is gathered on the lower electrode 22 side. Conduction between the source and the drain thereby occurs, so that the operation of the load 29 is resumed.

As described above, according to the semiconductor device 1B, as with the semiconductor device 1A, it is possible to interrupt the electronic circuit 28B at a high speed and prevent an accidental restoration before it is confirmed that the load 29 is in a normal state.

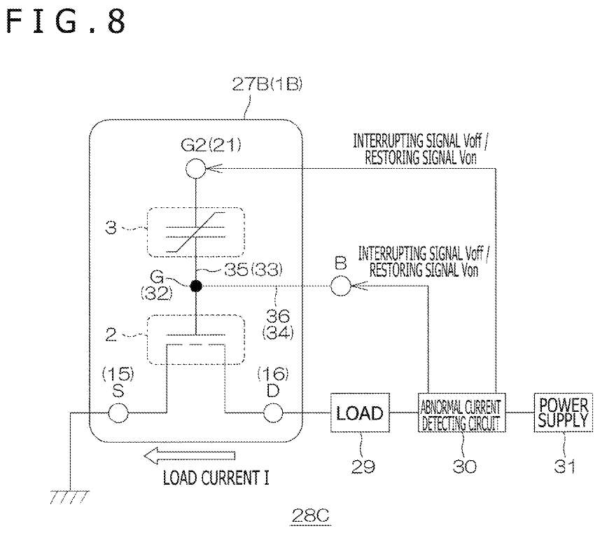

FIG. 8 is a diagram illustrating a second example of the connection circuit connecting the semiconductor device 1B of FIG. 5 to the load 29. The semiconductor device 1B having the circuit configuration of FIG. 6 may be incorporated in an electronic circuit 28C illustrated in FIG. 8, for example.

In the electronic circuit 28C of FIG. 8, a branch line 36 corresponding to the branch wiring 34 is connected to the intermediate line 35. A branch terminal B is formed at an end portion of the branch line 36. The other configuration is the same as that of the electronic circuit 28B of FIG. 7.

Description will be made of the detection of an abnormal current from a start of operation of the load 29 in the electronic circuit 28C and a subsequent restoring operation. Referring to FIG. 8, for example, the current interrupting element 27B is initialized to a normally-on state by a polling signal (for example, a voltage of ±5 V) to the nonvolatile memory 3.

Next, a voltage (for example, a voltage lower than −3 V) that is lower than the gate threshold voltage Vth of the field effect transistor 2 is applied to the second gate G2 in a state in which the branch terminal B is opened. Consequently, the positive charge (positive holes) and the negative charge (electrons) in the ferroelectric film 20 are spatially separated from each other, thus causing a spontaneous polarization. The two-dimensional electron gas 11 thereby disappears directly below the gate electrode 32 (gate G), so that the interruption between the source S and the drain D (source-to-drain) is effected. This process is to prevent an excessive voltage from being applied to the load 29 at a time of connecting the electronic circuit 28C to the power supply 31, and may be omitted as necessary.

Next, a voltage necessary for the operation of the load 29 is applied to the drain D. Then, the abnormal current detecting circuit 30 is connected between the power supply 31 and the load 29. Next, a voltage (for example, a voltage equal to or higher than −3 V) that is equal to or higher than the gate threshold voltage Vth is applied to the second gate G2. Consequently, a polarization reversal of the positive charge (positive holes) and the negative charge (electrons) in the ferroelectric film 20 occurs. The negative charge is gathered on the upper electrode 21 side. The positive charge is gathered on the lower electrode 22 side. The two-dimensional electron gas 11 occurs directly below the gate electrode 32 due to an electric attraction (attractive force) between the gate electrode 32 (gate G) consequently set to a positive potential and the electrons of the two-dimensional electron gas 11. In an operating state of the load 29, a load current I starts to flow between the source S and the drain D (source-to-drain) via the two-dimensional electron gas 11, and thus conduction occurs between the source and the drain.

When an abnormality occurs in the load 29, and an overcurrent flows between the source and the drain, for example, the interrupting signal Voff (<Gate Threshold Voltage Vth) that makes the second gate G2 side negative is input to the branch terminal B and the second gate G2 by a reaction of the abnormal current detecting circuit 30. Consequently, a polarization reversal of the positive charge (positive holes) and the negative charge (electrons) in the ferroelectric film 20 occurs. The positive charge is gathered on the upper electrode 21 side. The negative charge is gathered on the lower electrode 22 side (gate G). An interruption between the source and the drain is thereby effected, so that the operation of the load 29 is stopped.

Thereafter, the gate G is set in an open state. However, due to a characteristic of residual polarization of the nonvolatile memory 3 (ferroelectric film 20), the disappearance of the two-dimensional electron gas 11 between the source and the drain is continued, so that the interruption between the source and the drain is maintained.

When it is confirmed that the load 29 is in a normal state, the restoring signal Von (≥Gate Threshold Voltage Vth) that makes the second gate G2 side positive is input from the abnormal current detecting circuit 30 to the branch terminal B and the second gate G2. Consequently, a polarization reversal of the positive charge (positive holes) and the negative charge (electrons) in the ferroelectric film 20 occurs again. The negative charge is gathered on the upper electrode 21 side. The positive charge is gathered on the lower electrode 22 side (gate G side). Conduction between the source and the drain thereby occurs, so that the operation of the load 29 is resumed.

As described above, according to the semiconductor device 1B, as with the semiconductor device 1A, it is possible to interrupt the electronic circuit 28C at a high speed and prevent an accidental restoration before it is confirmed that the load 29 is in a normal state. Further, the branch terminal B is formed in the electronic circuit 28C. Thus, when a voltage is applied between the branch terminal B and the second gate G2, the voltage can be applied to the nonvolatile memory 3 independently in isolation from the field effect transistor 2.

In the present embodiment, the nonvolatile memory 3 is a ferroelectric capacitor and has a high dielectric constant. Therefore, it is difficult to distribute a high voltage to the nonvolatile memory 3 due to voltage division between the field effect transistor 2 and the nonvolatile memory 3, so that a considerably high voltage may be needed to effect a polarization of the ferroelectric film 20. Accordingly, by adopting a configuration that enables a voltage to be applied to the nonvolatile memory 3 independently, it is possible to apply the voltage to the nonvolatile memory 3 efficiently and polarize the ferroelectric film 20 easily.

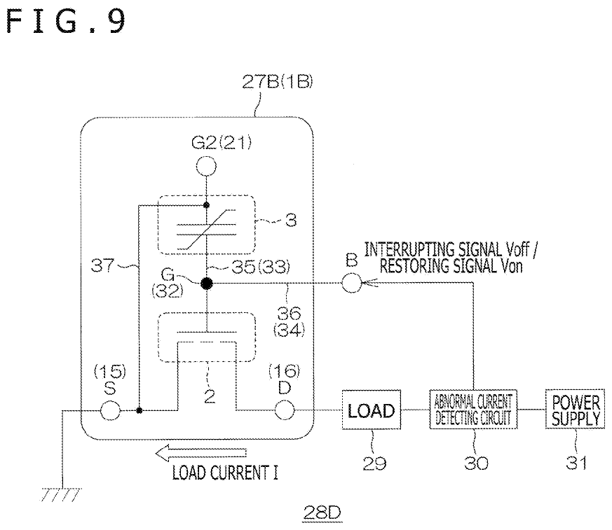

FIG. 9 is a diagram illustrating a third example of the connection circuit connecting the semiconductor device 1B of FIG. 5 to the load 29. The semiconductor device 1B having the circuit configuration of FIG. 6 may be incorporated in an electronic circuit 28D illustrated in FIG. 9, for example.

The electronic circuit 28D of FIG. 9 is provided with a ground line 37 that establishes a connection between the source S of the field effect transistor 2 and the second gate G2. The other configuration is the same as that of the electronic circuit 28C of FIG. 8.

In this electronic circuit 28D, the potential of the second gate G2 can be fixed at a ground potential. Thus, a stable voltage can be supplied between the branch terminal B and the second gate G2. That is, the interrupting signal Voff and the restoring signal Von can be applied stably with the second gate G2 (ground potential) as a reference.

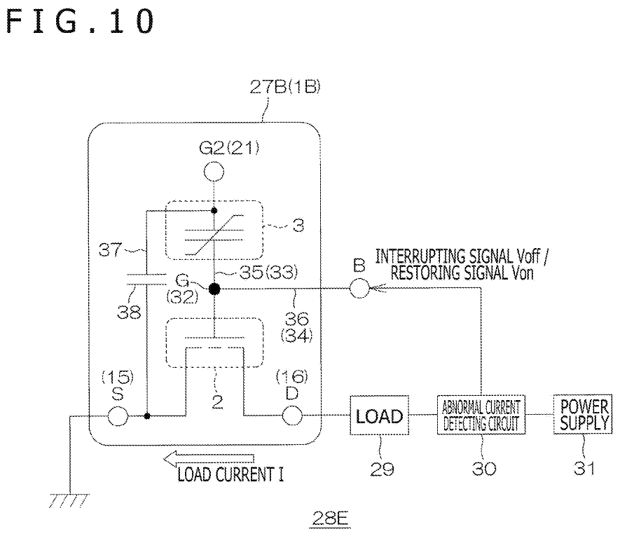

FIG. 10 is a diagram illustrating a fourth example of the connection circuit connecting the semiconductor device 1B of FIG. 5 to the load 29. The semiconductor device 1B having the circuit configuration of FIG. 6 may be incorporated in an electronic circuit 28E illustrated in FIG. 10, for example.

In the electronic circuit 28E of FIG. 10, the source S of the field effect transistor 2 and the second gate G2 are connected to each other via a capacitive element 38 formed on the ground line 37. The other configuration is the same as that of the electronic circuit 28D of FIG. 9.

Also in the electronic circuit 28E, the potential of the second gate G2 can be fixed at a ground potential. Thus, a stable voltage can be supplied between the branch terminal B and the second gate G2. That is, the interrupting signal Voff and the restoring signal Von can be applied stably with the second gate G2 (ground potential) as a reference.

### Third Embodiment

In the following, structures corresponding to the structures described with respect to the semiconductor devices 1A to 1B are identified by the same reference signs, and description thereof will be omitted.

### (1) Structure of Semiconductor Device 1C

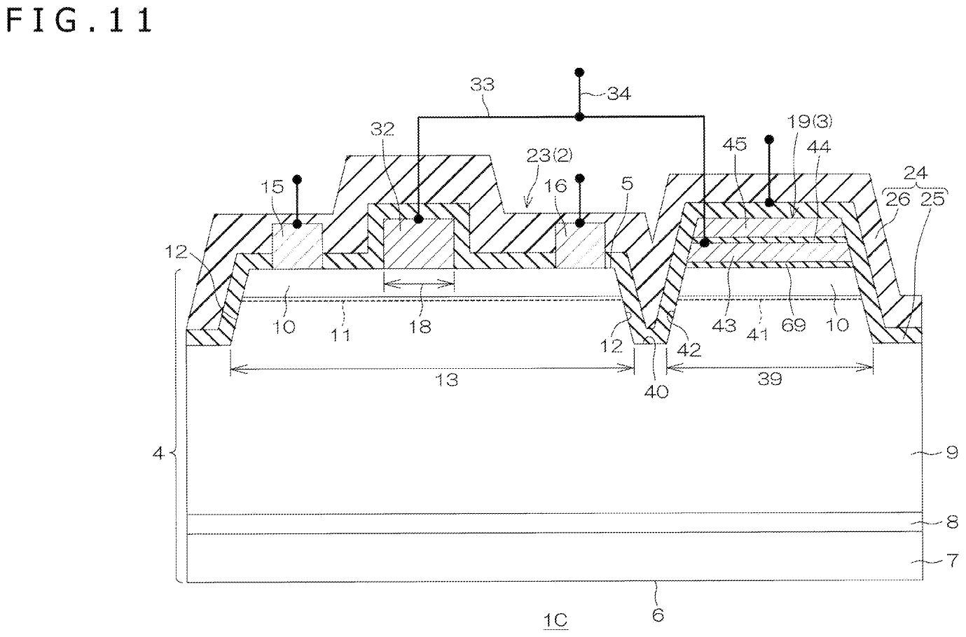

FIG. 11 is a schematic sectional view of a semiconductor device 1C according to a third embodiment of the present disclosure.

The semiconductor device 1C has a commonality with the semiconductor device 1A in that the semiconductor device 1C is provided with the transistor structure 23 and the memory structure 19 on the common semiconductor chip 4. On the other hand, in the semiconductor device 1C, the memory structure 19 is not laminated directly on the channel control region 18 as in the semiconductor device 1A, but is disposed in a region separated from the channel control region 18 along the principal surface of the semiconductor chip 4. More specifically, the semiconductor device 1C includes a second mesa laminated portion 39 for the memory structure 19.

The second mesa laminated portion 39 is separated from the mesa laminated portion 13 by a trench 40 that penetrates the second nitride semiconductor layer 10 and reaches the first nitride semiconductor layer 9. The trench 40 between the mesa laminated portion 13 and the second mesa laminated portion 39 divides two-dimensional electron gases 11 and 41 from each other.

The second mesa laminated portion 39 has a laminated structure of the first nitride semiconductor layer 9 and the second nitride semiconductor layer 10. Hence, the second mesa laminated portion 39 has a wall surface 42 that crosses the second nitride semiconductor layer 10 and the first nitride semiconductor layer 9 in the thickness direction. In the second mesa laminated portion 39, the two-dimensional electron gas 41 is spread within the first nitride semiconductor layer 9 and at a position close to the interface between the first nitride semiconductor layer 9 and the second nitride semiconductor layer 10. The two-dimensional electron gas 41 in the second mesa laminated portion 39 is electrically separated from the two-dimensional electron gas 11 in the mesa laminated portion 13 by the trench 40.

Further, in the present embodiment, the memory structure 19 includes a tunnel insulating film 69, a floating gate 43 formed on the tunnel insulating film 69, an intermediate insulating film 44 formed on the floating gate 43, and a control gate 45 formed on the intermediate insulating film 44.

The tunnel insulating film 69 is formed on the surface of the second nitride semiconductor layer 10 in the second mesa laminated portion 39, and is in contact with the second nitride semiconductor layer 10. The tunnel insulating film 69 is, for example, a SiO₂ (silicon oxide) film having a thickness approximately equal to or more than 8 nm and equal to or less than 12 nm. The tunnel insulating film 69 sets the floating gate 43 in an electrically floating state, and provides a path for a charge at a time of a signal input.

The floating gate 43 is formed on the tunnel insulating film 69, and is in contact with the tunnel insulating film 69. The floating gate 43 is, for example, polysilicon having a thickness approximately equal to or more than 1200 Å and equal to or less than 1800 Å. The floating gate 43 of the memory structure 19 and the gate electrode 32 are electrically connected to each other by the intermediate wiring 33. Branch wiring 34 branched from the intermediate wiring 33 may be further connected to a middle portion of the intermediate wiring 33.

The intermediate insulating film 44 is sandwiched between the floating gate 43 and the control gate 45, and insulates these gates from each other. The intermediate insulating film 44 is, for example, a film of an ONO (Oxide Film-Nitride Film-Oxide Film) structure in which a silicon nitride film is sandwiched between a pair of silicon oxide films. The thickness of the intermediate insulating film 44 is equal to or more than 10 nm and equal to or less than 30 nm, for example.

The control gate 45 is, for example, polysilicon having a thickness approximately equal to or more than 900 Å and equal to or less than 1300 Å. A silicide (not illustrated) may be formed on the sur-face of the control gate 45.

The memory structure 19 is covered by the passivation film 24. That is, the first insulating film 25 covers the memory structure 19, and the second insulating film 26 further covers the first insulating film 25.

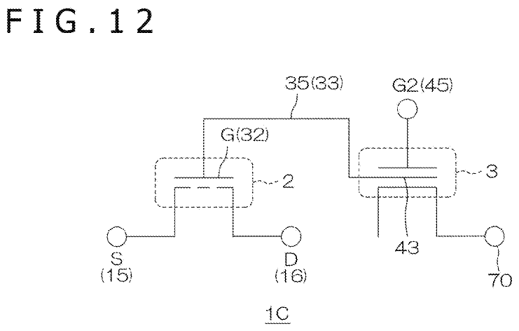

In using the semiconductor device 1C, a predetermined voltage (for example, equal to or higher than 1 V and equal to or lower than 40 V) that is positive on the drain electrode 16 side, for example, is applied between the source electrode 15 and the drain electrode 16. Because the semiconductor device 1C is a HEMT of the normally-on type, conduction occurs between the source and the drain via the two-dimensional electron gas 11 in this state. In order to effect interruption between the source and the drain, with the source electrode 15 set as a reference potential (0 V), a positive voltage is applied to the control gate 45, and a positive voltage is applied to a channel side terminal 70 (see FIG. 12).

Consequently, electrons are injected into the floating gate 43 due to Fowler-Nordheim (FN) tunneling from the two-dimensional electron gas 41 in the second mesa laminated portion 39 via the tunnel insulating film 69 and the second nitride semiconductor layer 10. As a result, the potential of the gate electrode 32 becomes the same potential (negative potential) as that of the floating gate 43 via the intermediate wiring 33. The two-dimensional electron gas 11 therefore disappears directly below the gate electrode 32 due to an electric repulsion (repulsive force) between the gate electrode 32 and the electrons of the two-dimensional electron gas 11 in the mesa laminated portion 13. The interruption between the source and the drain is thereby effected.

On the other hand, in order to effect conduction between the source and the drain again from the interrupted state, a negative voltage is applied to the control gate 45 with the source electrode 15 set at the reference potential (0 V). Consequently, electrons are released into the two-dimensional electron gas 41 in the second mesa laminated portion 39 due to FN tunneling from the floating gate 43 via the second nitride semiconductor layer 10. As a result, the potential of the gate electrode 32 becomes the same potential (positive potential) as that of the floating gate 43 via the intermediate wiring 33. The two-dimensional electron gas 11 therefore occurs directly below the gate electrode 32 due to an electric attraction (attractive force) between the gate electrode 32 and the electrons of the two-dimensional electron gas 11 in the mesa laminated portion 13. Thus, conduction occurs between the source and the drain.

### (2) Example of Connection Circuit of Semiconductor Device 1C

FIG. 12 is a diagram illustrating a circuit configuration of the semiconductor device 1C in FIG. 11. Referring to FIG. 11 and FIG. 12, the semiconductor device 1C includes a second gate G2 as an example of the second control terminal corresponding to the control gate 45. A connection between the gate G of the field effect transistor 2 and the nonvolatile memory 3 (floating gate 43) is established by the intermediate line 35 corresponding to the intermediate wiring 33. In addition, the channel side terminal 70 is connected to the nonvolatile memory 3.

As described above, as with the semiconductor device 1B, by being incorporated in the electronic circuits 28B to 28E described above, the semiconductor device 1C can also interrupt the electronic circuits 28B to 28E at a high speed and prevent an accidental restoration before it is confirmed that the load 29 is in a normal state. That is, an electric field from the gate electrode 32 of the field effect transistor 2 can be controlled by electron injection and release caused by the FN tunneling of the memory structure 19.

### Fourth Embodiment

In the following, structures corresponding to the structures described with respect to the semiconductor devices 1A to 1C are identified by the same reference signs, and description thereof will be omitted.

### (1) Structure of Semiconductor Device 1D

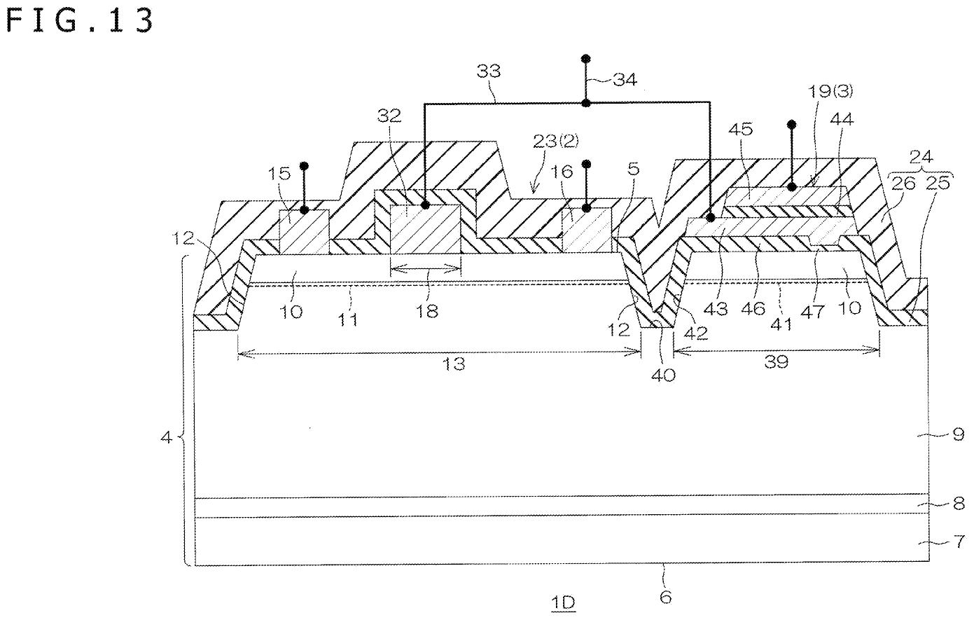

FIG. 13 is a schematic sectional view of a semiconductor device 1D according to a fourth embodiment of the present disclosure. In this semiconductor device 1D, the first insulating film 25 of the passivation film 24 is interposed as a tunnel insulating film 46 between the floating gate 43 and the second mesa laminated portion 39. The tunnel insulating film 46 may be formed by using a part of the first insulating film 25 as illustrated in FIG. 13, or may be formed by an insulating film independent of the passivation film 24.

The tunnel insulating film 46 includes a tunnel window 47 formed so as to be thinner than the tunnel insulating film 46 on the periphery of the tunnel window 47. The thickness of the tunnel window 47 may be, for example, equal to or more than 8 nm and equal to or less than 12 nm in a case where the thickness of the tunnel insulating film 46 on the periphery of the tunnel window 47 (part covered by the floating gate 43) is equal to or more than 20 nm and equal to or less than 100 nm.

### (2) Example of Connection Circuit of Semiconductor Device 1D

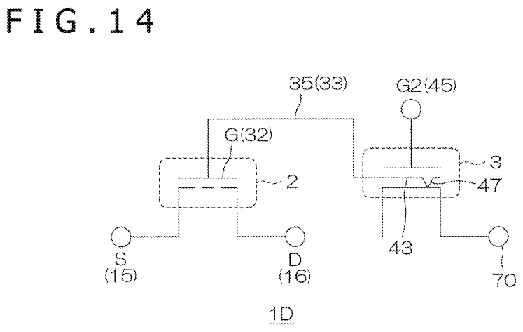

FIG. 14 is a diagram illustrating a circuit configuration of the semiconductor device 1D in FIG. 13. Referring to FIG. 13 and FIG. 14, the semiconductor device 1D includes a second gate G2 as an example of the second control terminal corresponding to the control gate 45. A connection between the gate G of the field effect transistor 2 and the nonvolatile memory 3 (floating gate 43) is established by the intermediate line 35 corresponding to the intermediate wiring 33.

As described above, as with the semiconductor devices 1B to 1C, by being incorporated in the electronic circuits 28B to 28E described above, the semiconductor device 1D can also interrupt the electronic circuits 28B to 28E at a high speed and prevent an accidental restoration before it is confirmed that the load 29 is in a normal state. That is, an electric field from the gate electrode 32 of the field effect transistor 2 can be controlled by electron injection and release caused by the FN tunneling of the memory structure 19.

### Fifth Embodiment

In the following, structures corresponding to the structures described with respect to the semiconductor devices 1A to 1D are identified by the same reference signs, and description thereof will be omitted.

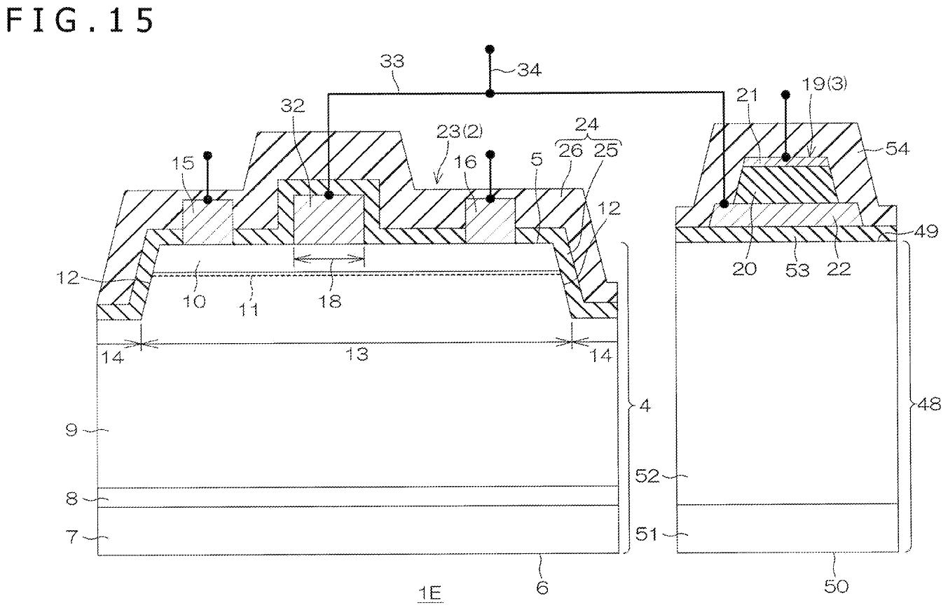

FIG. 15 is a schematic sectional view of a semiconductor device 1E according to a fifth embodiment of the present disclosure.

The semiconductor device 1E is similar to the semiconductor device 1B in that the semiconductor device 1E is provided with the memory structure 19 constituted by a ferroelectric capacitor. On the other hand, in the semiconductor device 1E, the memory structure 19 is formed on a second semiconductor chip 48 different from the semiconductor chip 4 of the field effect transistor 2.

The second semiconductor chip 48 has a first principal surface 49 and a second principal surface 50 that is on an opposite side from the first principal surface 49. The second semiconductor chip 48 includes a substrate 51 and an epitaxial layer 52 that is formed on the substrate 51.

The substrate 51 may be a silicon substrate, may be a sapphire substrate, or may be a substrate constituted by a wide band gap semiconductor. The wide band gap semiconductor may be SiC, diamond, or a nitride semiconductor.

The epitaxial layer 52 may be a silicon epitaxial layer, or may be an epitaxial layer constituted by a wide band gap semiconductor.

The substrate 51 and the epitaxial layer 52 may contain an impurity, or may not contain an impurity. In the present embodiment, the substrate 51 is an n⁺ type substrate. The epitaxial layer 52 is of an n-type. The n-type impurity concentration of the substrate 51 may be equal to or higher than 1.0×10¹⁵ cm⁻³ and equal to or lower than 1.0×10²¹ cm⁻³ (approximately 1.0×10¹⁸ cm⁻³, for example). The epitaxial layer 52 has an n-type impurity concentration lower than the n-type impurity concentration of the substrate 51. The n-type impurity concentration of the epitaxial layer 52 may be equal to or higher than 1.0×10¹⁵ cm⁻³ and equal to or lower than 1.0×10¹⁷ cm⁻³ (approximately 1.0×10¹⁶ cm⁻³, for example).

An insulating film 53 is formed on the first principal surface 49 of the second semiconductor chip 48. The insulating film 53 may be a SiO₂ film, for example. The memory structure 19 is formed on the insulating film 53. A passivation film 54 is formed so as to cover the memory structure 19.

In the present embodiment, the intermediate wiring 33 that connects the lower electrode 22 of the memory structure 19 and the gate electrode 32 to each other may be a bonding wire or other wires that straddles the semiconductor chip 4 and the second semiconductor chip 48.

As with the semiconductor devices 1B to 1D, by being incorporated in the electronic circuits 28B to 28E described above, the semiconductor device 1E can also interrupt the electronic circuits 28B to 28E at a high speed and prevent an accidental restoration before it is confirmed that the load 29 is in a normal state.

Incidentally, in the semiconductor device 1E, the semiconductor chip 4 and the second semiconductor chip 48 may be connected to each other in a form different from the connection via the bonding wire. For example, a chip-on-chip form may be adopted in which, on one of the semiconductor chip 4 and the second semiconductor chip 48, the other chip is mounted. In addition, a flip-chip form may be adopted in which one of the semiconductor chip 4 and the second semiconductor chip 48 is turned over and both of the chips are connected to each other via bumps, for example.

### Sixth Embodiment

In the following, structures corresponding to the structures described with respect to the semiconductor devices 1A to 1E are identified by the same reference signs, and description thereof will be omitted.

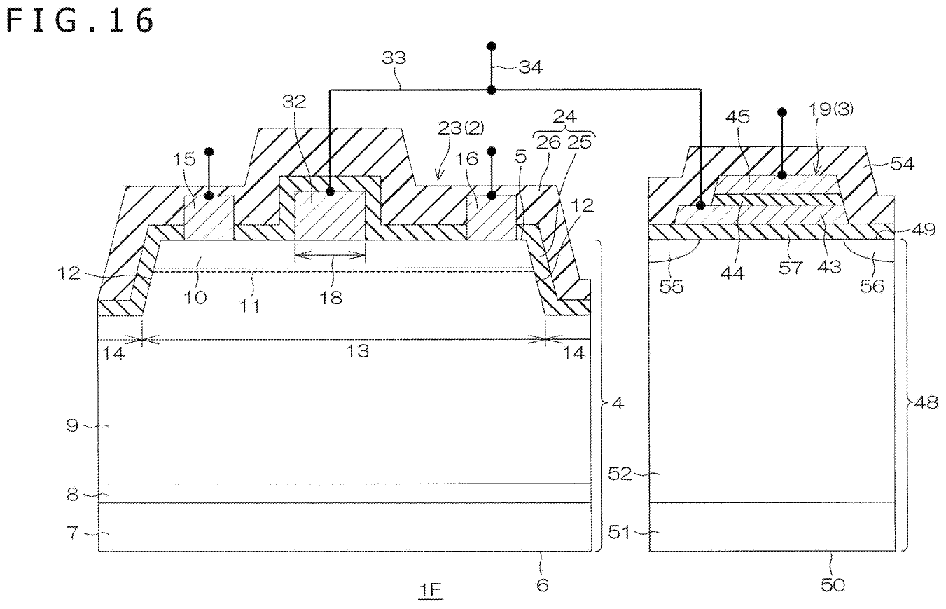

FIG. 16 is a schematic sectional view of a semiconductor device 1F according to a sixth embodiment of the present disclosure.

The semiconductor device 1F is different from the semiconductor device 1E provided with the memory structure 19 of the ferroelectric capacitor type in that the semiconductor device 1F is provided with a memory structure 19 of a flash memory type.

A source region 55 and a drain region 56 that face each other with the floating gate 43 interposed therebetween is formed in the first principal surface 49 of the second semiconductor chip 48 in the semiconductor device 1F. In the present embodiment, the substrate 51 and the epitaxial layer 52 may be of a p-type, and the source region 55 and the drain region 56 may be of an n-type.

A tunnel insulating film 57 is formed on the first principal surface 49 of the second semiconductor chip 48. A laminated structure of the floating gate 43, the intermediate insulating film 44, and the control gate 45 is formed on the tunnel insulating film 57.

In this semiconductor device 1F, when a positive voltage is applied to the control gate 45 and the drain region 56 in a state in which the source region 55 is set at the ground potential, for example, electrons are injected into the floating gate 43 by a hot electron current passing through the tunnel insulating film 57 from the source region 55. Alternatively, when a positive voltage is applied to the control gate 45 in a state in which the source region 55 and the drain region 56 are set at the ground potential, electrons are injected into the floating gate 43 by FN tunneling via the tunnel insulating film 57 from a channel region between the source and the drain.

On the other hand, as for the release of electrons from the floating gate 43, when a negative voltage is applied to the control gate 45, and a positive voltage is applied to the source region 55 or the drain region 56 or both the source region 55 and the drain region 56 in a state in which the drain region 56 is opened, for example, the electrons are released into the source region 55 by FN tunneling via the tunnel insulating film 57 from the floating gate 43.

As with the semiconductor devices 1B to 1E, by being incorporated in the electronic circuits 28B to 28E described above, the semiconductor device 1F can also interrupt the electronic circuits 28B to 28E at a high speed and prevent an accidental restoration before it is confirmed that the load 29 is in a normal state.

Incidentally, in the semiconductor device 1F, the semiconductor chip 4 and the second semiconductor chip 48 may be connected to each other in a form different from the connection via the bonding wire. For example, a chip-on-chip form may be adopted in which, on one of the semiconductor chip 4 and the second semiconductor chip 48, the other chip is mounted. In addition, a flip-chip form may be adopted in which one of the semiconductor chip 4 and the second semiconductor chip 48 is turned over and both of the chips are connected to each other via bumps, for example.

### Seventh Embodiment

In the following, structures corresponding to the structures described with respect to the semiconductor devices 1A to 1F are identified by the same reference signs, and description thereof will be omitted.

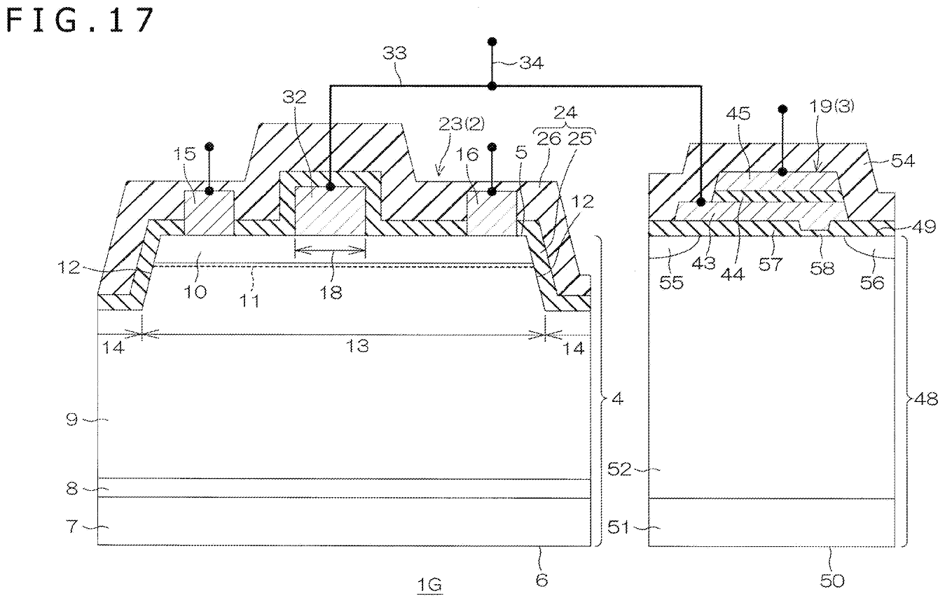

FIG. 17 is a schematic sectional view of a semiconductor device 1G according to a seventh embodiment of the present disclosure. In this semiconductor device 1G, the tunnel insulating film 57 includes a tunnel window 58 formed so as to be thinner than the tunnel insulating film 57 on the periphery of the tunnel window 58. The thickness of the tunnel window 58 may be, for example, equal to or more than 8 nm and equal to or less than 12 nm in a case where the thickness of the tunnel insulating film 57 on the periphery of the tunnel window 58 (part covered by the floating gate 43) is equal to or more than 20 nm and equal to or less than 100 nm.

As with the semiconductor devices 1B to 1F, by being incorporated in the electronic circuits 28B to 28E described above, the semiconductor device 1G can also interrupt the electronic circuits 28B to 28E at a high speed and prevent an accidental restoration before it is confirmed that the load 29 is in a normal state.

Incidentally, in the semiconductor device 1G, the semiconductor chip 4 and the second semiconductor chip 48 may be connected to each other in a form different from the connection via the bonding wire. For example, a chip-on-chip form may be adopted in which, on one of the semiconductor chip 4 and the second semiconductor chip 48, the other chip is mounted. In addition, a flip-chip form may be adopted in which one of the semiconductor chip 4 and the second semiconductor chip 48 is turned over and both of the chips are connected to each other via bumps, for example.

### Eighth Embodiment

In the following, structures corresponding to the structures described with respect to the semiconductor devices 1A to 1G are identified by the same reference signs, and description thereof will be omitted.

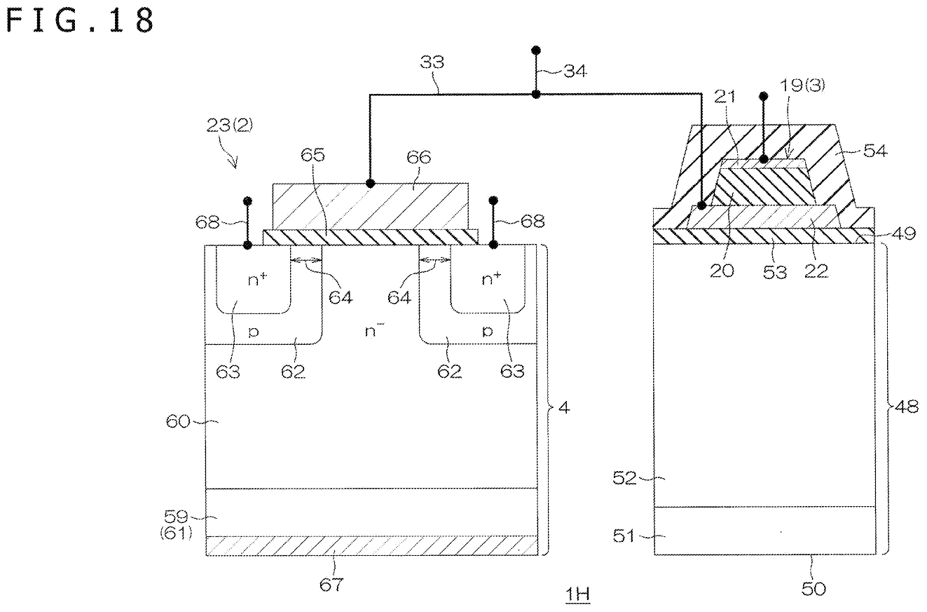

FIG. 18 is a schematic sectional view of a semiconductor device 1H according to an eighth embodiment of the present disclosure.

The semiconductor device 1H is different from the semiconductor device 1E provided with the transistor structure 23 having a HEMT structure in that the semiconductor device 1H is provided with a transistor structure 23 having a metal insulator semiconductor (MIS) structure.

In the semiconductor device 1H, the semiconductor chip 4 includes a substrate 59 and an epitaxial layer 60 that is formed on the substrate 59.

The substrate 59 may be a silicon substrate, or may be a substrate constituted by a wide band gap semiconductor. The wide band gap semiconductor may be SiC, diamond, or a nitride semiconductor.

The epitaxial layer 60 may be a silicon epitaxial layer, or may be an epitaxial layer constituted by a wide band gap semiconductor.

The substrate 59 and the epitaxial layer 60 may contain an impurity, or may not contain an impurity. In the present embodiment, the substrate 59 is an n⁺ type substrate. The substrate 59 may be an n-type drain region 61. The epitaxial layer 60 is of an n-type. The n-type impurity concentration of the substrate 59 may be equal to or higher than 1.0×10¹⁵ cm⁻³ and equal to or lower than 1.0×10²¹ cm⁻³ (approximately 1.0×10¹⁸ cm⁻³, for example). The epitaxial layer 60 has an n-type impurity concentration lower than the n-type impurity concentration of the substrate 59. The n-type impurity concentration of the epitaxial layer 60 may be equal to or higher than 1.0×10¹⁵ cm⁻³ and equal to or lower than 1.0×10¹⁷ cm⁻³ (approximately 1.0×10¹⁶ cm⁻³, for example).

P-type body regions 62 are formed in the first principal surface 5 of the semiconductor chip 4 (surface of the epitaxial layer 60). In surface portions of the p-type body regions 62, n-type source regions 63 are formed. Source electrodes 68 are connected to the source regions 63. In the p-type body regions 62, regions between outer circumferential edges thereof and the source regions 63 are channel control regions 64 in which a channel is formed.

A gate insulating film 65 is formed on the first principal surface 5 of the semiconductor chip 4. A gate electrode 66 as an example of the control electrode is formed on the gate insulating film 65. The gate electrode 66 faces the channel control regions 64 via the gate insulating film 65. The gate electrode 66 is connected to the lower electrode 22 of the memory structure 19 via the intermediate wiring 33.

A drain electrode 67 is formed on the second principal surface 6 of the semiconductor chip 4 (undersurface of the substrate 59).

As with the semiconductor devices 1B to 1G, by being incorporated in the electronic circuits 28B to 28E described above, the semiconductor device 1H can also interrupt the electronic circuits 28B to 28E at a high speed and prevent an accidental restoration before it is confirmed that the load 29 is in a normal state. The memory structure 19 connected to the MIS type transistor structure 23 is not limited to the ferroelectric capacitor type in FIG. 18, but may be the memory structure 19 of the flash memory type illustrated in FIG. 16 and FIG. 17.

Incidentally, in the semiconductor device 1H, the semiconductor chip 4 and the second semiconductor chip 48 may be connected to each other in a form different from the connection via the bonding wire. For example, a chip-on-chip form may be adopted in which, on one of the semiconductor chip 4 and the second semiconductor chip 48, the other chip is mounted. In addition, a flip-chip form may be adopted in which one of the semiconductor chip 4 and the second semiconductor chip 48 is turned over and both of the chips are connected to each other via bumps, for example.

Embodiments of the present disclosure have been described. However, the present disclosure can be carried out in other modes.

For example, in the foregoing embodiments, description has been made of an example in which a first conductivity type is an n-type and a second conductivity type is a p-type. However, the first conductivity type may be a p-type, and the second conductivity type may be an n-type. Concrete configurations in this case are obtained by replacing n-type regions with p-type regions and replacing p-type regions with n-type regions in the foregoing description and the accompanying drawings.

In addition, the transistor structure 23 is not limited to the HEMT or the metal insulator semiconductor field effect transistor (MISFET) described above, but may be an insulated-gate bipolar transistor (IGBT). In a case of an IGBT, it suffices to make the substrate 59 in FIG. 18 a p-type substrate (collector region).

The foregoing embodiments of the present disclosure are illustrative in all respects and are not to be construed as restrictive, and are intended to include changes in all respects.

Features appended in the following can be extracted from the description of the present specification and the drawings.

### [Supplementary Note 1-1]

A semiconductor device (1A to 1H) including:
a field effect transistor (2) that has a first terminal (D) connected to a load (29), a second terminal (S) conducting to the first terminal (D) via a channel, and a control terminal (G) that controls conduction and interruption of the channel by an electric field; and
a nonvolatile memory (3) that is a nonvolatile memory (3) connected to the control terminal (G) and has a second control terminal (G2) supplied with a voltage that changes a direction of the electric field from the control terminal (G).

According to this configuration, the voltage supplied to the second control terminal (G2) is controlled appropriately when an abnormality occurs in the load (29). Consequently, the direction of an electric field from the control terminal (G) is changed, so that the channel of the field effect transistor (2) is interrupted. Thus, a current flowing through the load (29) can be interrupted. As a result, a circuit including the load (29) and a circuit adjacent to the circuit including the load (29) can be protected. In addition, the load (29) circuit is interrupted by switching operation of the field effect transistor (2), and can therefore be interrupted at a high speed as compared with other current interrupting elements (for example, a fuse and a poly-switch). An abnormal mode that occurs in the load (29) may include, for example, an overcurrent, a short circuit, heating, a reverse current, an overvoltage, and a low voltage.

In addition, an element that controls the electric field direction of the field effect transistor (2) is the nonvolatile memory (3). Therefore, unless a restoring signal for restoring the nonvolatile memory (3) to an initial state is intentionally input to the nonvolatile memory (3) after the interruption of the channel, the interruption is maintained without the conduction of the channel. Hence, it is possible to prevent an accidental conduction of the channel of the field effect transistor (2) and a flow of a current to the load (29) before it is confirmed that the load (29) is in a normal state.

### [Supplementary Note 1-2]

The semiconductor device (1B to 1H) according to supplementary note 1-1, further including:
an intermediate line (35) that establishes a connection between the control terminal (G) and the nonvolatile memory (3); and
a branch terminal (B) branched from the intermediate line (35).

According to this configuration, a voltage can be applied between the branch terminal (B) and the second control terminal (G2). Thus, a voltage can be applied to the nonvolatile memory (3) independently in isolation from the field effect transistor (2). Even when it is difficult to distribute a relatively high voltage to the nonvolatile memory (3) due to voltage division between the field effect transistor (2) and the nonvolatile memory (3), it is possible to apply the voltage to the nonvolatile memory (3) efficiently and thereby control the nonvolatile memory (3).

### [Supplementary Note 1-3]

The semiconductor device (1B to 1H) according to supplementary note 1-1 or 1-2, in which
the second terminal (S) is grounded, and
the semiconductor device (1B to 1H) further includes a ground line (37) that establishes a connection between the second terminal (S) and the second control terminal (G2).

According to this configuration, the potential of the second control terminal (G2) can be fixed at a ground potential. Thus, a stable voltage can be supplied between the branch terminal (B) and the second control terminal (G2).

### [Supplementary Note 1-4]

The semiconductor device (1B to 1H) according to supplementary note 1-3, in which
the second terminal (S) and the second control terminal (G2) are connected to each other via a capacitive element (38) formed on the ground line (37).

### [Supplementary Note 1-5]

The semiconductor device (1A to 1D) according to any one of supplementary notes 1-1 to 1-4, including:
a semiconductor chip (4), in which
the field effect transistor (2) includes a transistor structure (23) that has a first electrode (16 or 67) as the first terminal (D) electrically connected to the semiconductor chip (4), a second electrode (15 or 68) as the second terminal (S) electrically connected to the semiconductor chip (4), and a channel control region (18) formed between the first electrode (16 or 67) and the second electrode (15 or 68), and
the nonvolatile memory (3) includes a memory structure (19) formed on the semiconductor chip (4) that is in common with the transistor structure (23).

According to this configuration, it is possible to provide, on one chip, the semiconductor device (1A to 1D) that can interrupt the load circuit at a high speed and prevent an accidental restoration before it is confirmed that the load (29) is in a normal state.

### [Supplementary Note 1-6]

The semiconductor device (1A) according to supplementary note 1-5, in which
the memory structure (19) includes a ferroelectric film (20) laminated directly on the channel control region (18) and an upper electrode (21) as the second control terminal (G2) laminated on the ferroelectric film (20), and,
due to polarization of the ferroelectric film (20), the polarization being caused by the supply of the voltage to the upper electrode (21), the direction of the electric field from the channel control region (18) as the control terminal (G) changes, and the conduction and interruption of the channel are controlled.

According to this configuration, the memory structure (19) is laminated, as a gate portion (17) of the field effect transistor (2), directly on the channel control region (18). It is thereby possible to reduce wiring losses at times of control of the conduction and interruption of the channel by the memory structure (19).

### [Supplementary Note 1-7]

The semiconductor device (1A) according to supplementary note 1-6, in which
the memory structure (19) further includes a lower electrode (22) sandwiched between the ferroelectric film (20) and the channel control region (18).

According to this configuration, the lower electrode (22) can hinder the diffusion of a ferroelectric material into the semiconductor chip (4). It is thereby possible to suppress a change in the characteristics of the field effect transistor (2).

### [Supplementary Note 1-8]

The semiconductor device (1B to 1D) according to supplementary note 1-5, in which
the transistor structure (23) includes a control electrode (32) as the control terminal (G) laminated directly on the channel control region (18),
the memory structure (19) is disposed in a region (14) separated from the channel control region (18) along a principal surface (5) of the semiconductor chip (4), and
the semiconductor device (1B to 1D) includes intermediate wiring (33) that connects the memory structure (19) and the control electrode (32) to each other.

According to this configuration, a voltage can be applied between the intermediate wiring (33) and the second control terminal (G2). Thus, a voltage can be applied to the nonvolatile memory (3) independently in isolation from the field effect transistor (2). Even when it is difficult to distribute a relatively high voltage to the nonvolatile memory (3) due to voltage division between the field effect transistor (2) and the nonvolatile memory (3), it is possible to apply the voltage to the nonvolatile memory (3) efficiently and thereby control the nonvolatile memory (3).

### [Supplementary Note 1-9]

The semiconductor device (1B) according to supplementary note 1-8, in which
the memory structure (19) includes a ferroelectric film (20), and a lower electrode (22) and an upper electrode (21) as the second control terminal (G2), the lower electrode (22) and the upper electrode (21) sandwiching the ferroelectric film (20),
the intermediate wiring (33) connects the control electrode (32) and the lower electrode (22) to each other, and,
due to polarization of the ferroelectric film (20), the polarization being caused by the supply of the voltage to the upper electrode (21), the direction of the electric field from the control electrode (32) changes, and the conduction and interruption of the channel are controlled.

### [Supplementary Note 1-10]

The semiconductor device (1C to 1D) according to supplementary note 1-8, in which
the memory structure (19) includes a tunnel insulating film (46 or 69), a floating gate (43) formed on the tunnel insulating film (46 or 69), an intermediate insulating film (44) formed on the floating gate (43), and a control gate (45) as the second control terminal (G2) formed on the intermediate insulating film (44),
the intermediate wiring (33) connects the control electrode (32) and the floating gate (43) to each other, and,
due to injection and release of electrons or positive holes into the floating gate (43), the injection and release being caused by control of a voltage to the control gate (45), the direction of the electric field from the control electrode (32) changes, and the conduction and interruption of the channel are controlled.

### [Supplementary Note 1-11]

The semiconductor device (1D) according to supplementary note 1-10, in which
the tunnel insulating film (46) includes a tunnel window (47) formed so as to be thinner than the tunnel insulating film (46) on a periphery of the tunnel window (47).

### [Supplementary Note 1-12]

The semiconductor device (1A to 1B) according to any one of supplementary notes 1-6, 1-7, and 1-9, in which
the ferroelectric film (20) is any one of a single crystal PZT (lead zirconate titanate) thin film, a polycrystalline PZT thin film, and a BST ((Ba, Sr) TiO₃) thin film.

### [Supplementary Note 1-13]

The semiconductor device (1A to 1G) according to any one of supplementary notes 1-1 to 1-11, in which
the transistor structure (23) includes a high electron mobility transistor structure (23) including an electron transit layer formed by a first nitride semiconductor layer (9) in the semiconductor chip (4) and an electron supply layer formed by a second nitride semiconductor layer (10) on the first nitride semiconductor layer (9).

### [Supplementary Note 1-14]

The semiconductor device (1A to 1G) according to supplementary note 1-13, in which
the high electron mobility transistor structure (23) includes a normally-on-type high electron mobility transistor structure (23).

According to this configuration, it is not necessary to apply a voltage at all times in order to make the channel conduct. Hence, a power supply circuit for the transistor structure (23) can be omitted, so that the semiconductor device (1A to 1G) having a simple structure can be provided.

### [Supplementary Note 1-15]

The semiconductor device (1H) according to any one of supplementary notes 1-1 to 1-11, in which
the transistor structure (23) includes a metal insulator semiconductor transistor structure (23) including a source region (63) of a first conductivity type, the source region (63) being formed on the semiconductor chip (4), a drain region (61) of the first conductivity type, the drain region (61) being formed on the semiconductor chip (4), a body region (62) of a second conductivity type, the body region (62) being formed between the source region (63) and the drain region (61), and a gate electrode (66) as the control electrode that faces the channel control region (64) formed by a part of the body region (62).

### [Supplementary Note 1-16]

The semiconductor device (1A to 1H) according to any one of supplementary notes 1-1 to 1-15, in which
the transistor structure (23) includes a power transistor structure (23).

### [Supplementary Note 1-17]

The semiconductor device (1A to 1H) according to supplementary note 1-16, in which
the semiconductor chip (4) includes a Si substrate, a SiC substrate, or a sapphire substrate.

According to one embodiment of the present disclosure, it is possible to provide a semiconductor device that can interrupt a load circuit at a high speed and prevent an accidental restoration of the load circuit.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a field effect transistor that has a first terminal connected to a load, a second terminal conducting to the first terminal via a channel, and a control terminal that controls conduction and interruption of the channel by an electric field; and
a nonvolatile memory that is a nonvolatile memory connected to the control terminal and has a second control terminal supplied with a voltage that changes a direction of the electric field from the control terminal.

2. The semiconductor device according to claim 1, further comprising:
an intermediate line that establishes a connection between the control terminal and the nonvolatile memory; and
a branch terminal branched from the intermediate line.

3. The semiconductor device according to claim 1, wherein
the second terminal is grounded, and
the semiconductor device further includes a ground line that establishes a connection between the second terminal and the second control terminal.

4. The semiconductor device according to claim 3, wherein
the second terminal and the second control terminal are connected to each other via a capacitive element formed on the ground line.

5. The semiconductor device according to claim 1, comprising:
a semiconductor chip, wherein
the field effect transistor includes a transistor structure that has a first electrode as the first terminal electrically connected to the semiconductor chip, a second electrode as the second terminal electrically connected to the semiconductor chip, and a channel control region formed between the first electrode and the second electrode, and
the nonvolatile memory includes a memory structure formed on the semiconductor chip that is in common with the transistor structure.

6. The semiconductor device according to claim 5, wherein
the memory structure includes a ferroelectric film laminated directly on the channel control region and an upper electrode as the second control terminal laminated on the ferroelectric film, and,
due to polarization of the ferroelectric film, the polarization being caused by the supply of the voltage to the upper electrode, the direction of the electric field from the channel control region as the control terminal changes, and the conduction and interruption of the channel are controlled.

7. The semiconductor device according to claim 6, wherein
the memory structure further includes a lower electrode sandwiched between the ferroelectric film and the channel control region.

8. The semiconductor device according to claim 5, wherein
the transistor structure includes a control electrode as the control terminal laminated directly on the channel control region,
the memory structure is disposed in a region separated from the channel control region along a principal surface of the semiconductor chip, and
the semiconductor device includes intermediate wiring that connects the memory structure and the control electrode to each other.

9. The semiconductor device according to claim 8, wherein
the memory structure includes a ferroelectric film, and a lower electrode and an upper electrode as the second control terminal, the lower electrode and the upper electrode sandwiching the ferroelectric film,
the intermediate wiring connects the control electrode and the lower electrode to each other, and,
due to polarization of the ferroelectric film, the polarization being caused by the supply of the voltage to the upper electrode, the direction of the electric field from the control electrode changes, and the conduction and interruption of the channel are controlled.

10. The semiconductor device according to claim 8, wherein
the memory structure includes a tunnel insulating film, a floating gate formed on the tunnel insulating film, an intermediate insulating film formed on the floating gate, and a control gate as the second control terminal formed on the intermediate insulating film,
the intermediate wiring connects the control electrode and the floating gate to each other, and,
due to injection and release of electrons or positive holes into the floating gate, the injection and release being caused by control of a voltage to the control gate, the direction of the electric field from the control electrode changes, and the conduction and interruption of the channel are controlled.

11. The semiconductor device according to claim 10, wherein
the tunnel insulating film includes a tunnel window formed so as to be thinner than the tunnel insulating film on a periphery of the tunnel window.

12. The semiconductor device according to claim 6, wherein
the ferroelectric film is any one of a single crystal PZT (lead zirconate titanate) thin film, a polycrystalline PZT thin film, and a BST ((Ba, Sr) TiO₃) thin film.

13. The semiconductor device according to claim 5, wherein
the transistor structure includes a high electron mobility transistor structure including an electron transit layer formed by a first nitride semiconductor layer in the semiconductor chip and an electron supply layer formed by a second nitride semiconductor layer on the first nitride semiconductor layer.

14. The semiconductor device according to claim 13, wherein
the high electron mobility transistor structure includes a normally-on-type high electron mobility transistor structure.

15. The semiconductor device according to claim 8, wherein
the transistor structure includes a metal insulator semiconductor transistor structure including a source region of a first conductivity type, the source region being formed on the semiconductor chip, a drain region of the first conductivity type, the drain region being formed on the semiconductor chip, a body region of a second conductivity type, the body region being formed between the source region and the drain region, and a gate electrode as the control electrode that faces the channel control region formed by a part of the body region.

16. The semiconductor device according to claim 5, wherein
the transistor structure includes a power transistor structure.

17. The semiconductor device according to claim 16, wherein
the semiconductor chip includes a Si substrate, a SiC substrate, or a sapphire substrate.
